(19) United States
(12) Patent Application Publication
(10) Pub. No.: US 2003/0002360 A1
(43) Pub. Date: Jan. 2, 2003

(54) Device for and method of storing identification data in an integrated circuit

(75) Inventors: Edgar Rieger, Graz (AT); Stefan Posch, Graz (AT); Johann Vorreiter, Graz (AT)

Correspondence Address: Corporate Patent Counsel, U.S. Philips Corporation, 580 White Plains Road, Tarrytown, NY, 10591, US

(73) Assignee: Koninklijke Philips Electronics N.V.

(21) Appl. No.: 10/179,354

(22) Filed: Jun. 25, 2002

(30) Foreign Application Priority Data
Jun. 27, 2001 (EP) 01 890 200.7

(51) Int. Cl. G11C 29/00

(52) U.S. Cl. 365/200

(57) ABSTRACT

In a device (1), which is preferably a test device (1), there are provided data generating means (5) for generating device identification data (DIDA) significant with regard to the device (1) itself, which device identification data (DIDA) may be fed to an integrated circuit (2) introduced into the device (1), the integrated circuit (2) comprising a memory (12), with a memory area (13) which is provided and designed to store the device identification data (DIDA)

The invention relates to a device for storing identification data in an integrated circuit.

The invention further relates to a method of writing identification data into an integrated circuit.

The invention further relates to an integrated circuit with memory means for storing identification data.

Such a device, such a method and such an integrated circuit have long been known among the experts. In this context, reference may be made, for example, to the following patent documents, namely U.S. Pat. No. 6,018,686 A, US 5,642,307 A, US 6,154,872 A and US 5,369,747 A.

With the known solutions, it is already known to store the most varied identification data in an integrated circuit, in order, after manufacture of such an integrated circuit, to be able to draw conclusions regarding manufacture and testing. For example, it is known to store identification data in an integrated circuit which are significant with regard to place of manufacture, date of manufacture, the original position of an integrated circuit in a wafer, the result of a testing procedure and the like.

It is likewise already known to store in an integrated circuit an identification number unique to this integrated circuit, which identification number offers the possibility of being able at any time to identify unambiguously the relevant integrated circuit. It was hitherto conventional to issue such identification numbers for integrated circuits from a central office of a manufacturer of such integrated circuits, even if manufacture of such integrated circuits took place at different production sites. A specific quota of such unique identification numbers was then made available for each production site, which quota was then issued to the relevant production site. It has emerged that this procedure is disadvantageous insofar as a relatively large number of unused identification numbers was wasted. It has further emerged that certain data and information relating to the manufacture and testing of integrated circuits were not contained in the identification numbers issued hitherto, which causes problems in some instances of application.

It is an object of the invention to eliminate the above-described problems and to provide an improved device, an improved method and an improved integrated circuit.

To achieve the above-mentioned object, features according to the invention are provided for a device according to the invention, so that a device according to the invention may be characterized in the following way, namely:

A device for storing identification data in an integrated circuit, which device comprises first data generating means for generating device identification data significant with regard to the device itself.

To achieve the above-mentioned object, features according to the invention are provided for a method according to the invention, so that a method according to the invention may be characterized in the following way, namely:

A method of writing identification data into an integrated circuit, in which method device identification data are generated, which device identification data are significant with regard to a device itself designed for storing identification data in an integrated circuit and are stored in memory means of the integrated circuit.

To achieve the above-mentioned object, features according to the invention are provided for an integrated circuit according to the invention, so that such an integrated circuit according to the invention may be characterized in the following way, namely:

An integrated circuit with memory means for storing identification data, wherein the memory means comprise a first memory area, which first memory area is designed for storing device identification data, which device identification data are significant with regard to a device for storing the identification data.

By providing the features according to the invention, it is possible, in a very simple manner and with very little additional effort, to ensure that, during manufacture of an integrated circuit, device identification data are generated, which device identification data are significant with regard to a device itself designed to store identification data in an integrated circuit, so that, in the case of a finished integrated circuit, device identification data are stored in this integrated circuit which are significant with regard to that device itself by means of which identification data for the integrated circuit were stored in the relevant integrated circuit, so that the great, hitherto unachieved advantage is obtained that, in the case of a finished integrated circuit, it may also be established with which device identification data stored in the integrated circuit have been stored. This provides the advantage that, even in the event of there being a plurality of devices at one production site for storing identification data in an integrated circuit, each of these devices may subsequently be refindable or traceable by means of the device identification data stored in an integrated circuit, which is of particularly great advantage when, in the case of an integrated circuit, shortcomings are discovered after completion thereof which may be attributed to the device for storing identification data.

A further advantage is achieved by providing the measures according to the invention in that, due to use of the device identification data, it is no longer essential for unique identification numbers for integrated circuits to be issued from a central office, but rather they may advantageously be issued in decentralized manner by each device for storing identification data in integrated circuits, because the unique identification numbers may be distinguished from one another in a simple manner in that the device identification data contained in each of these unique identification numbers are identified.

The measures according to the invention are particularly important and advantageous when the device for storing identification data in an integrated circuit is a test device for testing the integrated circuit. In this case, it has proven highly advantageous for data words to be stored in an integrated circuit as device identification data, which data words store the site of the relevant test device and additionally the number that was issued to this test device.

In connection with the above-described measures according to the invention, it has proven highly advantageous for count data to be stored in an integrated circuit in addition to the device identification data, which count data represent the number of wafers with integrated circuits processed by a device for storing identification data in an integrated circuit. This advantageously ensures the unique nature of the identification number stored in an integrated circuit.

In addition, it has proven advantageous, in connection with the above-mentioned measures, for position data also to be stored in an integrated circuit in addition to the device identification data and optionally the count data, which position data represent a position of the integrated circuit on a wafer. Although this measure is already known per se, it is also advantageous in the context of the present invention.

The above-stated aspects of the invention and further aspects thereof emerge from the example of embodiment described below and are explained with reference to this example of embodiment.

The invention will be further described with reference to an example of embodiment shown in the drawings, to which, however, the invention is not restricted.

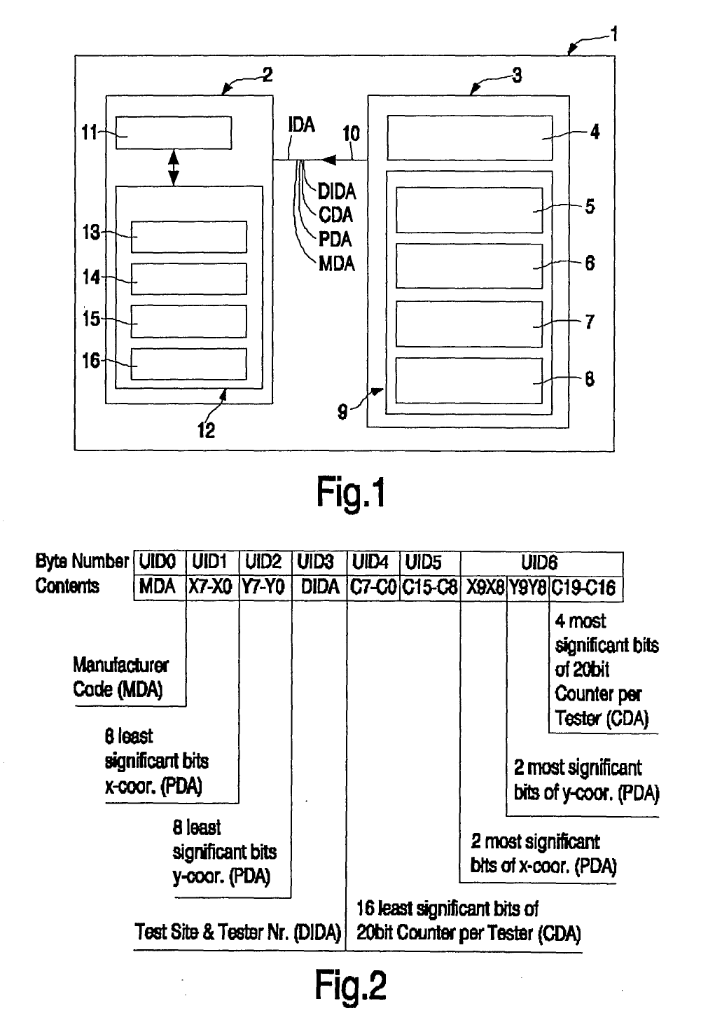

FIG. 1 is a highly schematic representation, in the form of a block diagram, of a device according to an example of embodiment of the invention, consisting of a test device for an integrated circuit.

FIG. 2 shows schematically identification data which are stored in an integrated circuit according to an example of embodiment of the invention.

FIG. 1 shows a device 1 for storing identification data IDA in an integrated circuit 2. In this instance, the device 1 is a test device 1, by means of which the integrated circuit 2 may be tested in order to check that the integrated circuit 2 is in proper service condition.

The test device 1 comprises test means 3, which exhibit a test stage 4 by means of which test procedures may be executed to test an integrated circuit 2 introduced into the test device 1 and located on a wafer. The stated test procedures and the introduction of the integrated circuit 2 into the test device 1 are not examined here in any more detail, since they are not relevant in the present context.

The test means 3 further comprise first data generating means 5, second data generating means 6, third data generating means 7 and fourth data generating means 8. The four above-mentioned data generating means 5, 6, 7 and 8 are components of data processing means 9 of the test means 3. The first data generating means 5 are provided and designed to generate device identification data DIDA significant with regard to the test device 1 itself. The device identification data DIDA here consist of data which represent the site of the test device 1 and the number of the test device 1, which number was issued either by the manufacturer of the integrated circuit 2 or by the manufacturer of the test device 1. The second data generating means 6 are provided and designed to generate count data CDA. The count data CDA represent the number of wafers tested by the test device 1. The third data generating means 7 are provided and designed to generate position data PDA. The position data PDA represent the position of an integrated circuit 2 on a wafer. This may be that position which an integrated circuit 2 occupied on a wafer before separation from said wafer. The fourth data generating means 8 are provided and designed to generate manufacturer data MDA. The manufacturer data MDA are significant with regard to the manufacturer of an integrated circuit 2.

In the course of testing an integrated circuit, the identification data IDA generated by means of the test means 3, i.e. the device identification data DIDA and the count data CDA and the position data PDA and the manufacturer data MDA, are preferably transmitted at the end of said testing via a connection 10 indicated schematically in FIG. 1 to the integrated circuit 2 introduced into the test device 1.

The integrated circuit 2 comprises IC data processing means 12, by means of which data transmitted to the integrated circuit 2 may be processed and by means of which data contained in the integrated circuit 2 may likewise be processed. The integrated circuit 2 further comprises memory means 12. The memory means 12 are provided and designed to store a plurality of data, which will not be examined overall in any more detail here. It should however be noted in the present instance that the memory means 12 comprise a first memory area 13, a second memory area 14, a third memory area 15 and a fourth memory area 16.

The first memory area 13 is provided and designed to store device identification data DIDA. The second memory area 14 is provided and designed to store count data CDA. The third memory area 15 is provided and designed to store position data PDA. The fourth memory area 16 is provided and designed to store manufacturer data MDA.

FIG. 2 is a schematic representation of a data word as an example of a possible configuration of identification data. This data word consists of a total of seven bytes, which bytes exhibit the byte numbers UID0, UID1, UID2, UID3, UID4, UID5 and UID6. The manufacturer data MDA are stored in the byte bearing the byte number UID0. The eight least significant bits of position data PDA representing the x coordinate are stored in the byte bearing byte number UID1. The eight least significant bits of position data PDA representing the y coordinate are stored in the byte bearing byte number UID2. The device identification data DIDA are stored in the byte bearing byte number UID3, i.e. those data which represent the site of the test device 1 and the number of the test device 1. The sixteen least significant bits of the count data CDA are stored in the two bytes bearing byte numbers UID4 and UID5, these being the sixteen least significant bits of a 20 bit counter of the test device 1, which 20 bit counter is a component of the second data generating means 6 of the test means 3. The two most significant bits of the position data PDA representing the x coordinate, followed by the two most significant bits of the position data PDA representing the y coordinate and then the four most significant bits of the count data CDA, constituting the four most significant bits of the 20 bit counter of the test device 1, are stored in succession in the byte bearing byte number UID6.

It may be mentioned that both the test stage 4 and the data processing means 9 may take the form of a microcomputer or a hard-wired logic circuit. In a preferred construction using a microcomputer, the 20 bit counter may simply take the form of a count variable. The count variable is increased from a starting value, for example decimal zero (0), by a value, for example decimal one (1), if a new wafer with integrated circuits is introduced into the test device 1, so that, when identification data IDA are subsequently stored in further integrated circuits, it is ensured that the identification data IDA are unique, i.e. no integrated circuits may occur which have identical identification data IDA, since a test device's combinations of position data PDA and count data CDA always differ. It should be mentioned that the 20 bit counter may be reduced from another starting value, for example the maximum value which the 20 bit counter is capable of displaying, by a value, for example one (1). Such and other counter manipulations are known to a person skilled in the art, for which reason they will not be examined in any more detail here.

It may be mentioned that the count data CDA may likewise represent the number of storing processes performed with regard to identification data IDA. In this respect, the 20 bit counter is always increased for example by a value one (1) if storage of the identification data IDA in an integrated circuit has been successful, so that the uniqueness of the identification data IDA is ensured in the case of successive storage of identification data IDA in further integrated circuits. Understandably, the yield achievable with this method is lower than with the method using “wafer counting”, i.e. fewer integrated circuits with unique identification data IDA are possible.

1. A device (1) for storing identification data (IDA) in an integrated circuit (2),
which device (1) comprises first data generating means (5) for generating device identification data (DIDA) significant with regard to the device (1) itself.

2. A device (1) as claimed in claim 1,
in which second data generating means (6) are provided for generating count data (CDA), which count data (CDA) represent the number of wafers with integrated circuits processed with the device (1).

3. A device (1) as claimed in claim 1 or claim 2,
in which the device (1) takes the form of a test device (1) for testing the integrated circuit.

4. A method of writing identification data (IDA) into an integrated circuit (2),
in which method device identification data (DIDA) are generated, which device identification data (DIDA) are significant with regard to a device (1) itself designed for storing identification data (IDA) in an integrated circuit (2) and are stored in memory means (12) of the integrated circuit (2).

5. A method as claimed in claim 4,
in which count data (CDA) are generated, which count data (CDA) represent the number of wafers with integrated circuits processed with the device (1) and which count data (CDA) are stored in memory means (12) of the integrated circuit (2).

6. A method as claimed in claim 4 or claim 5,
in which position data (PDA) are additionally generated, which position data (PDA) represent a position of the integrated circuit (2) on a wafer and are stored in memory means (12) of the integrated circuit (2).

7. An integrated circuit (2) with memory means (12) for storing identification data (IDA), in which the memory means (12) comprise a first memory area (13), which first memory area (13) is designed for storing device identification data (DIDA), which device identification data (DIDA) are significant with regard to a device (1) for storing in the identification data (IDA).

8. An integrated circuit (2) as claimed in claim 7,
in which the memory means (12) comprise a second memory area (14), which second memory area (14) is designed for storing count data (CDA), which count data (CDA) represent the number of wafers with integrated circuits processed with the device (1).

9. An integrated circuit (2) as claimed in claim 7 or claim 8,
in which the memory means (12) comprise a third memory area (15), which third memory area (15) is designed for storing position data (PDA), which position data (PDA) represent a position of the integrated circuit (2) on a wafer.
